(19) United States
(12) Patent Application Publication
(10) Pub. No.: US 2025/0291113 A1
(43) Pub. Date: Sep. 18, 2025

(54) OPTICAL TERMINATOR, OPTICAL WAVELENGTH FILTER, AND EXTERNAL CAVITY LASER LIGHT SOURCE

(71) Applicant: Mitsubishi Electric Corporation, Tokyo (JP)

(72) Inventor: Masakazu TAKABAYASHI, Chiyoda-ku, Tokyo (JP)

(73) Assignee: Mitsubishi Electric Corporation, Tokyo (JP)

(21) Appl. No.: 18/863,349

(22) PCT Filed: Jun. 8, 2022
(86) PCT No.: PCT/JP2022/023168

§ 371 Date: Nov. 6, 2024

(51) Int. Cl. G02B 6/24; H01S 5/10; H01S 5/14

(52) U.S. Cl. CPC G02B 6/241; H01S 5/101; H01S 5/142

(57) ABSTRACT

An optical terminator includes a first termination waveguide. The first termination waveguide includes a curved waveguide and a curved waveguide. The curved waveguide includes only one maximum curvature portion. The curved waveguide includes only one maximum curvature portion. A first normal vector of the curved waveguide at the maximum curvature portion and a second normal vector of the curved waveguide at the maximum curvature portion are oriented in the same direction.

### TECHNICAL FIELD

The present disclosure relates to an optical terminator, an optical wavelength filter, and an external cavity laser light source.

### BACKGROUND ART

Japanese Patent Laying-Open No. 2021-39277 (PTL 1) discloses an optical terminator including a tapered portion and a curved structure portion.

### CITATION LIST

### Patent Literature

PTL 1: Japanese Patent Laying-Open No. 2021-39277

### SUMMARY OF INVENTION

### Technical Problem

However, since the length of the curved structure portion is short in the optical terminator disclosed in PTL 1, reflection of light cannot be sufficiently suppressed in the optical terminator. Further, since the curved structure portion of the optical terminator disclosed in PTL 1 has a curvature unchanged over the entire curved structure portion, emission light emitted from the curved structure portion cannot have directivity.

The present disclosure has been made in view of the above-described problem and an object of a first aspect of the present disclosure is to provide an optical terminator to further suppress reflection of light and improve directivity of emission light emitted from the optical terminator. An object of a second aspect of the present disclosure is to provide an optical wavelength filter to more precisely tune a wavelength of light to be selected by the optical wavelength filter, An object of a third aspect of the present disclosure is to provide an external cavity laser light source to precisely align an optical amplifier with the optical wavelength filter and set a wavelength to be selected by the optical wavelength filter.

### Solution to Problem

An optical terminator according to the present disclosure includes: a substrate including a main surface; and a first termination waveguide formed on the main surface of the substrate. The first termination waveguide includes a first end, a first curved waveguide, a second curved waveguide, and a second end opposite to the first end. The second curved waveguide is connected to the first curved waveguide and is disposed close to the second end with respect to the first curved waveguide. The first curved waveguide includes only one first maximum curvature portion. The first maximum curvature portion is a portion having a maximum curvature in the first curved waveguide. The second curved waveguide includes only one second maximum curvature portion. The second maximum curvature portion is a portion having a maximum curvature in the second curved waveguide. In a plan view of the main surface of the substrate, a first normal vector of the first curved waveguide at the first maximum curvature portion and a second normal vector of the second curved waveguide at the second maximum curvature portion are oriented in the same direction.

An optical wavelength filter according to the present disclosure includes: the optical terminator according to the present disclosure; a ring resonator; and a refractive index regulator. The ring resonator is connected to the first end. The refractive index regulator regulates a refractive index of the ring resonator.

An external cavity laser light source according to the present disclosure includes: the optical wavelength filter according to the present disclosure; and an optical amplifier optically coupled to the ring resonator.

### Advantageous Effects of Invention

In the optical terminator according to the present disclosure, light having entered the optical terminator is emitted from the first curved waveguide and the second curved waveguide. The intensity of the light to reach the second end of the optical terminator is decreased. The optical terminator can further suppress reflection of light. Further, since the first normal vector and the second normal vector are oriented in the same direction, the directivity of the emission light emitted from the optical terminator can be improved.

The emission light from the optical terminator according to the present disclosure has higher intensity and higher directivity. Therefore, in the optical wavelength filter according to the present disclosure, the wavelength of the light to be selected by the optical wavelength filter can be more precisely tuned based on the emission light from the optical terminator.

The emission light from the optical terminator according to the present disclosure has higher intensity and higher directivity. Therefore, in the external cavity laser light source according to the present disclosure, it is possible to more precisely align the optical amplifier with the optical wavelength filter and set a wavelength to be selected by the optical wavelength filter based on the emission light from the optical terminator.

### BRIEF DESCRIPTION OF DRAWINGS

FIG. 1 is a schematic plan view of an optical wavelength filter according to each of first to fourth embodiments.

FIG. 2 is a schematic cross sectional view of the optical wavelength filter according to the first embodiment along a cross sectional line II-II shown in FIG. 1.

FIG. 3 is a schematic plan view of a ring resonator included in the optical wavelength filter according to the first embodiment.

FIG. 4 shows a graph representing an exemplary spectrum of light output from a through port of the ring resonator.

FIG. 5 shows a graph representing an exemplary spectrum of light output from a drop port of the ring resonator.

FIG. 6 is a schematic partial enlarged plan view of an optical terminator according to the first embodiment.

FIG. 7 shows a graph representing a change in curvature of the optical terminator according to the first embodiment.

FIG. 8 is a schematic partial enlarged plan view of an optical terminator according to a second embodiment.

FIG. 9 shows a graph representing a change in curvature of the optical terminator according to the second embodiment.

FIG. 10 is a schematic partial enlarged plan view of an optical terminator according to a modification of the second embodiment.

FIG. 11 shows a graph representing a change in curvature of the optical terminator according to the modification of the second embodiment.

FIG. 12 is a schematic partial enlarged plan view of an optical terminator according to a third embodiment.

FIG. 13 is a schematic partial enlarged plan view of an optical terminator according to a fourth embodiment.

FIG. 14 is a schematic partial enlarged plan view of an optical terminator according to a modification of the fourth embodiment.

FIG. 15 is a schematic plan view of an external cavity laser light source according to a fifth embodiment.

FIG. 16 is a schematic cross sectional view of an optical amplifier included in the external cavity laser light source according to the fifth embodiment along a cross sectional line XVI-XVI shown in FIG. 15.

### DESCRIPTION OF EMBODIMENTS

Hereinafter, embodiments of the present disclosure will be described. It should be noted that the same configurations are denoted by the same reference characters and will not be described repeatedly.

### First Embodiment

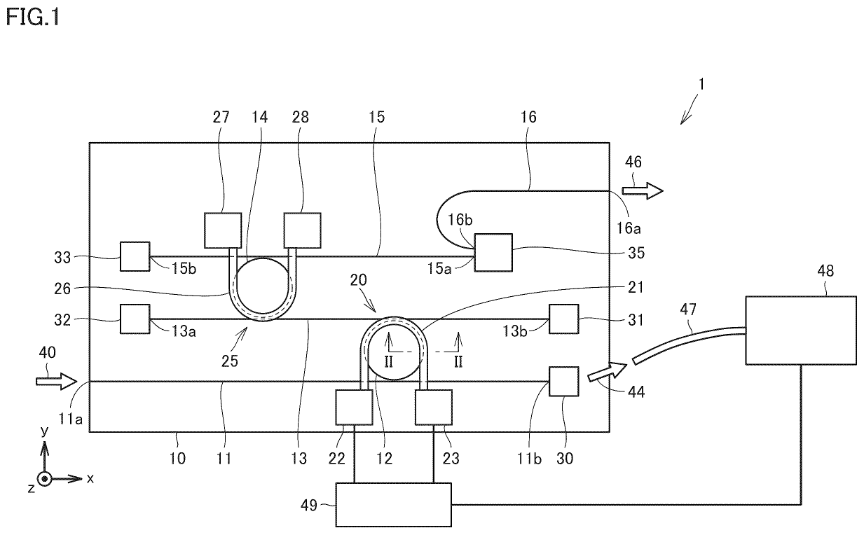

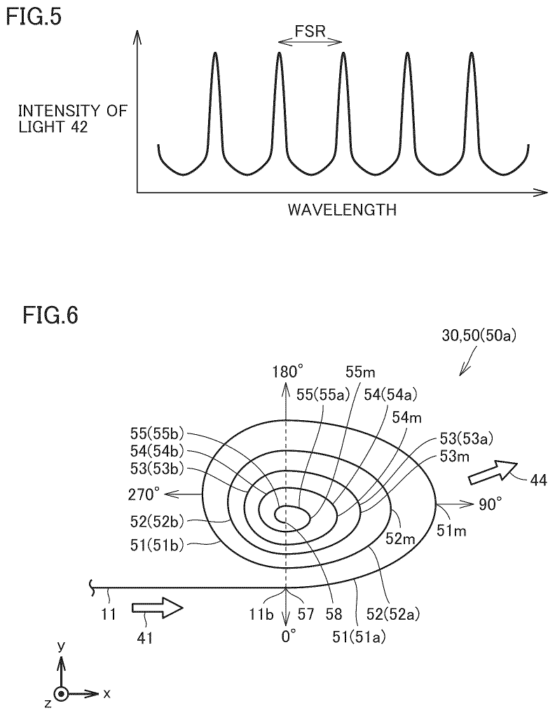

An optical wavelength filter 1 according to a first embodiment will be described with reference to FIGS. 1 to 6. Optical wavelength filter 1 mainly includes ring resonators 20, 25, optical terminators 30, 31, 32, 33, a spectrum analyzer 48, and a controller 49. Optical wavelength filter 1 may further include a mirror 35, a waveguide 16, and an optical fiber 47. Ring resonator 20 includes waveguides 11, 13, a ring waveguide 12, a refractive index regulator 21, and electrode pads 22, 23. Ring resonator 25 includes waveguides 13, 15, a ring waveguide 14, a refractive index regulator 26, and electrode pads 27, 28. Each of optical terminators 30, 31, 32, 33 includes a first termination waveguide 50 (see FIG. 6).

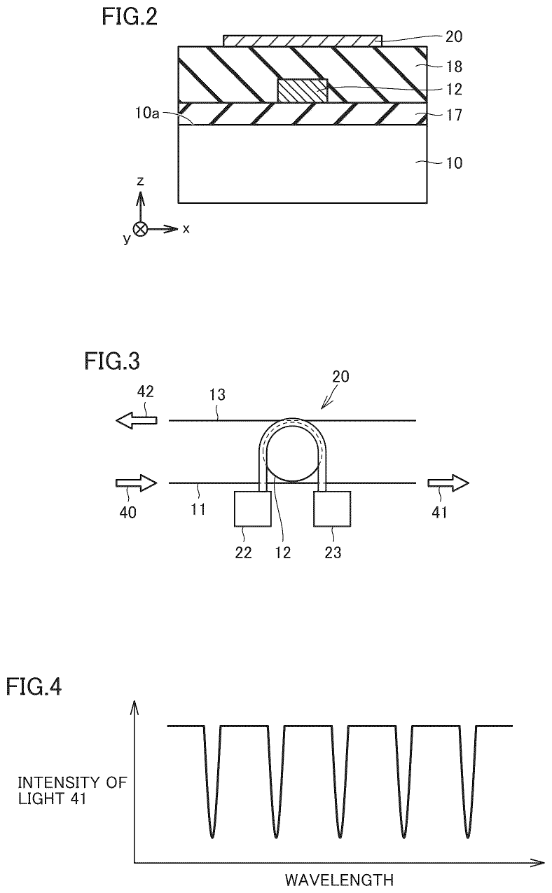

Waveguides 11, 13, 15, 16, ring waveguides 12, 14, and first termination waveguide 50 are formed on a main surface 10a (see FIG. 2) of a substrate 10. Substrate 10 is, for example, a silicon substrate. Substrate 10 may be a compound semiconductor substrate such as an InP substrate or may be a glass substrate. Substrate 10 includes main surface 10a. Main surface 10a extends in an x direction and a y direction perpendicular to the x direction. A normal direction of main surface 10a is a z direction perpendicular to the x direction and the y direction. In the present specification, the expression “a waveguide is formed on main surface 10a of substrate 10” means that the waveguide is formed on main surface 10a of substrate 10 with a lower cladding layer 17 (see FIG. 2) being interposed therebetween, or means that the waveguide is formed directly on main surface 10a of substrate 10. Each of waveguides 11, 13, 15, 16, ring waveguides 12, 14, and first termination waveguide 50 may be covered with an upper cladding layer 18 (see FIG. 2).

Each of waveguides 11, 13, 15, 16, ring waveguides 12, 14, and first termination waveguide 50 has a higher refractive index than that of each of lower cladding layer 17 and upper cladding layer 18. Therefore, the light propagates through waveguides 11, 13, 15, 16, ring waveguides 12, 14, and first termination waveguide 50. Each of lower cladding layer 17 and upper cladding layer 18 is composed of, for example, SiO₂. Each of waveguides 11, 13, 15, 16, ring waveguides 12, 14, and first termination waveguide 50 is composed of, for example, silicon. Each of waveguides 11, 13, 15, 16, ring waveguides 12, 14, and first termination waveguide 50 may be composed of quartz or may be composed of a semiconductor material.

As shown in FIG. 1, waveguide 11 extends, for example, in the x direction. Waveguide 11 includes an end 11a and an end 11b opposite to end 11a. End 11a is an entrance end of optical wavelength filter 1 and is an input port of ring resonator 20. End 11b of waveguide 11 is a through port of ring resonator 20 and is connected to optical terminator 30.

Waveguide 13 extends, for example, along waveguide 11. Waveguide 13 extends, for example, in the x direction. Waveguide 13 includes an end 13a and an end 13b opposite to end 13a. Waveguide 13 is optically coupled to ring waveguide 12 and ring waveguide 14. Ring waveguide 12 is disposed close to end 13b with respect to ring waveguide 14. Ring waveguide 14 is disposed close to end 13a with respect to ring waveguide 12. Waveguide 13 includes a drop port of ring resonator 20, an input port of ring resonator 25, and a through port of ring resonator 25. The drop port of ring resonator 20 is connected to the input port of ring resonator 25. End 13a of waveguide 13 is the through port of ring resonator 25 and is connected to optical terminator 32. End 13b of waveguide 13 is connected to optical terminator 31.

Waveguide 15 extends, for example, along waveguide 13. Waveguide 15 extends, for example, in the x direction. Waveguide 15 includes an end 15a and an end 15b opposite to end 15a. End 15b of waveguide 15 is connected to optical terminator 33. Waveguide 15 is optically coupled to ring waveguide 14. Waveguide 15 includes a drop port of ring resonator 25. End 15a of waveguide 15 is the drop port of ring resonator 25 and is connected to mirror 35.

Mirror 35 reflects, to waveguide 16, a whole or part of light having entered from end 15a of waveguide 15. Mirror 35 is, for example, a dielectric multilayer mirror inserted in a groove formed in each cladding layer (upper cladding layer 18 and lower cladding layer 17). Waveguide 16 includes an end 16a and an end 16b opposite to end 16a. End 16b of waveguide 16 faces mirror 35. A whole or part of the light reflected by mirror 35 enters end 16b of waveguide 16 and exits as light 46 from end 16a of waveguide 16. End 16a of waveguide 16 is an exit end of optical wavelength filter 1.

A wavelength selection function of ring resonator 20 will be described with reference to FIGS. 1 and 3 to 5.

Light 40 enters from the input port (end 11a) of ring resonator 20. Depending on a wavelength of light 40, light 40 travels through waveguide 11 without being coupled to ring waveguide 12 and becomes light 41 to exit from the through port (end 11b) of ring resonator 20 (see FIGS. 3 and 4), or is coupled to waveguide 13 via ring waveguide 12 and becomes light 42 to exit from the drop port of ring resonator 20 (see FIGS. 3 and 5). As shown in FIG. 5, the wavelength of light 42 to exit from the drop port of ring resonator 20 is defined by a refractive index n of ring waveguide 12 and a length L of ring waveguide 12. A free spectral range (FSR) of ring resonator 20 is given by a formula (1). The FSR of ring resonator 20 is a frequency interval at which a ratio of optical coupling from the input port of ring resonator 20 to the drop port of ring resonator 20 is maximum. Therefore, the wavelength of light 42 to be output from the drop port of ring resonator 20 can be selected. Ring resonator 20 functions as an optical wavelength filter.

$$FSR = c / ( nL ) \qquad ( 1 )$$

Here, c represents the speed of light in vacuum.

Refractive index regulator 21 regulates the refractive index of ring waveguide 12. Therefore, ring resonator 20 functions as a wavelength tunable filter. Specifically, the refractive index of ring waveguide 12 is changed by refractive index regulator 21. The free spectrum range (FSR) of ring resonator 20 is changed, thereby changing the wavelength of light 42 to be coupled to the drop port of ring resonator 20.

In the present embodiment, ring waveguide 12 is composed of a material having a thermo-optic effect such as silicon, and each of refractive index regulators 21, 26 is a thin-film heater that can apply heat to ring waveguide 12. The thin-film heater is composed of, for example, a high-resistance metal material such as tantalum, platinum, or titanium. Refractive index regulator 21 is connected to electrode pads 22, 23. Power is supplied to refractive index regulator 21 through electrode pads 22, 23.

The through port (end 11a) of ring resonator 20 is connected to optical terminator 30. The power to be supplied to refractive index regulator 21 is regulated based on emission light 44 emitted from optical terminator 30.

Specifically, spectrum analyzer 48 receives emission light 44 from optical terminator 30 via optical fiber 47. Spectrum analyzer 48 obtains a spectrum of emission light 44. Controller 49 is connected to spectrum analyzer 48. Controller 49 receives the spectrum of emission light 44 from spectrum analyzer 48. Controller 49 controls the power to be supplied to refractive index regulator 21, based on the spectrum of emission light 44. The temperature of refractive index regulator 21 is appropriately regulated, thereby appropriately regulating the refractive index of ring waveguide 12. For example, the power to be supplied to refractive index regulator 21 is regulated to attain a minimum spectral intensity of the wavelength, to be selected by optical wavelength filter 1, of emission light 44 from optical terminator 30. This leads to a maximum ratio of optical coupling, to the drop port of ring resonator 20, of the light having the wavelength to be selected by optical wavelength filter 1.

Ring resonator 25 operates as a wavelength tunable filter as with ring resonator 20. The power to be supplied to refractive index regulator 26 is also controlled by controller 49 as with refractive index regulator 21. For example, the power to be supplied to refractive index regulator 26 is regulated based on emission light emitted from optical terminator 32. However, the length of ring waveguide 14 is different from the length of ring waveguide 12. Therefore, the FSR of ring resonator 25 is different from the FSR of ring resonator 20.

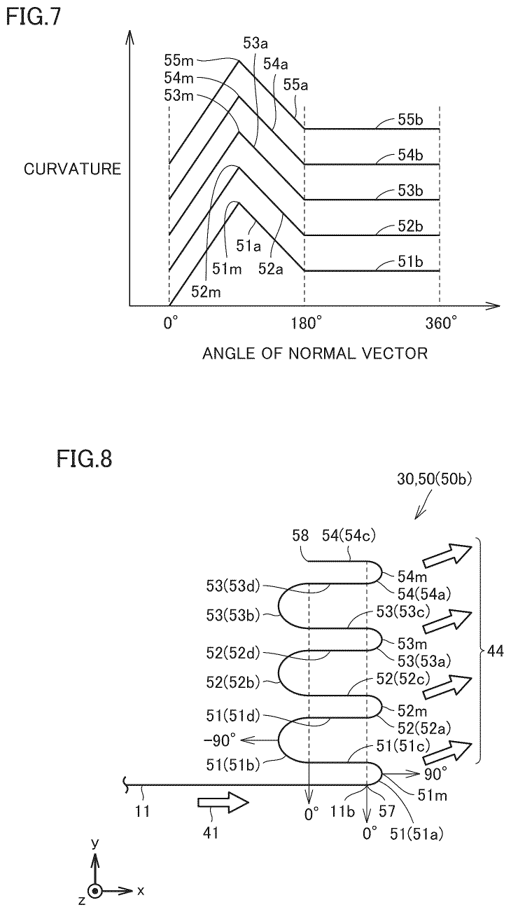

Each of optical terminators 31, 32, 33 is configured in the same manner as optical terminator 30 and functions in the same manner as optical terminator 30. Therefore, optical terminator 30 will be described in detail with reference to FIGS. 6 and 7.

Optical terminator 30 includes substrate 10 (see FIGS. 1 and 2) and first termination waveguide 50 formed on main surface 10a of substrate 10. Optical terminator 30 may further include lower cladding layer 17 (see FIG. 2) and upper cladding layer 18 (see FIG. 2). In the plan view of main surface 10a of substrate 10, first termination waveguide 50 is a spiral waveguide 50a. First termination waveguide 50 includes a first end 57, curved waveguides 51, 52, 53, 54, 55, and a second end 58 opposite to first end 57.

First end 57 of first termination waveguide 50 is connected to end 11b of waveguide 11, which is the through port of ring resonator 20. First end 57 is an optical input end of optical terminator 30. Second end 58 is a terminal end of optical terminator 30. Second end 58 is located at the center of the spiral of first termination waveguide 50.

Curved waveguide 51 includes first end 57 and is connected to end 11b of waveguide 11. In the plan view of main surface 10a of substrate 10, curved waveguide 51 has a shape of spiral wounded once. Curved waveguide 51 includes only one maximum curvature portion 51m. Maximum curvature portion 51m is a portion having a maximum curvature in curved waveguide 51. Curved waveguide 51 includes a curved waveguide portion 51a and a curved waveguide portion 51b.

Curved waveguide portion 51a is connected to waveguide 11 and includes first end 57 of first termination waveguide 50. Curved waveguide portion 51a is expanded toward outside of substrate 10 (for example, in the +x direction (see FIG. 1)) in the plan view of main surface 10a of substrate 10. Curved waveguide portion 51a includes maximum curvature portion 51m. Curved waveguide portion 51b is connected to curved waveguide portion 51a. Curved waveguide portion 51b is disposed close to second end 58 with respect to curved waveguide portion 51a. Curved waveguide portion 51b is expanded toward inside of substrate 10 (for example, in the −x direction (see FIG. 1)) in the plan view of main surface 10a of substrate 10.

Curved waveguide 52 is connected to curved waveguide 51. In the plan view of main surface 10a of substrate 10, curved waveguide 52 has a shape of spiral wound once. Curved waveguide 52 is disposed internal to curved waveguide 51. Curved waveguide 52 is disposed close to second end 58 with respect to curved waveguide 51. Curved waveguide 52 includes only one maximum curvature portion 52m. Maximum curvature portion 52m is a portion having a maximum curvature in curved waveguide 52. Curved waveguide 52 includes a curved waveguide portion 52a and a curved waveguide portion 52b.

Curved waveguide portion 52a is connected to curved waveguide portion 51b. Curved waveguide portion 52a is expanded toward the outside of substrate 10 (for example, in the +x direction (see FIG. 1)) in the plan view of main surface 10a of substrate 10. Curved waveguide portion 52a includes maximum curvature portion 52m. Curved waveguide portion 52b is connected to curved waveguide portion 52a. Curved waveguide portion 52b is disposed close to second end 58 with respect to curved waveguide portion 52a. Curved waveguide portion 52b is expanded toward the inside of substrate 10 (for example, in the −x direction (see FIG. 1)) in the plan view of main surface 10a of substrate 10.

Curved waveguide 53 is connected to curved waveguide 52. In the plan view of main surface 10a of substrate 10, curved waveguide 53 has a shape of spiral wound once. Curved waveguide 53 is disposed internal to curved waveguide 52. Curved waveguide 53 is disposed close to second end 58 with respect to curved waveguide 52. Curved waveguide 53 includes only one maximum curvature portion 53m. Maximum curvature portion 53m is a portion having a maximum curvature in curved waveguide 53. Curved waveguide 53 includes a curved waveguide portion 53a and a curved waveguide portion 53b.

Curved waveguide portion 53a is connected to curved waveguide portion 52b. Curved waveguide portion 53a is expanded toward the outside of substrate 10 (for example, in the +x direction (see FIG. 1)) in the plan view of main surface 10a of substrate 10. Curved waveguide portion 53a includes maximum curvature portion 53m. Curved waveguide portion 53b is connected to curved waveguide portion 53a. Curved waveguide portion 53b is disposed close to second end 58 with respect to curved waveguide portion 53a. Curved waveguide portion 53b is expanded toward the inside of substrate 10 (for example, in the −x direction (see FIG. 1)) in the plan view of main surface 10a of substrate 10.

Curved waveguide 54 is connected to curved waveguide 53. In the plan view of main surface 10a of substrate 10, curved waveguide 54 has a shape of spiral wound once. Curved waveguide 54 is disposed internal to curved waveguide 53. Curved waveguide 54 is disposed close to second end 58 with respect to curved waveguide 53. Curved waveguide 54 includes only one maximum curvature portion 54m. Maximum curvature portion 54m is a portion having the maximum curvature in curved waveguide 54. Curved waveguide 54 includes a curved waveguide portion 54a and a curved waveguide portion 54b.

Curved waveguide portion 54a is connected to curved waveguide portion 53b. Curved waveguide portion 54a is expanded toward the outside of substrate 10 (for example, in the +x direction (see FIG. 1)) in the plan view of main surface 10a of substrate 10. Curved waveguide portion 54a includes maximum curvature portion 54m. Curved waveguide portion 54b is connected to curved waveguide portion 54a. Curved waveguide portion 54b is disposed close to second end 58 with respect to curved waveguide portion 54a. Curved waveguide portion 54b is expanded toward the inside of substrate 10 (for example, in the −x direction (see FIG. 1)) in the plan view of main surface 10a of substrate 10.

Curved waveguide 55 includes second end 58 and is connected to curved waveguide 54. In the plan view of main surface 10a of substrate 10, curved waveguide 55 has a shape of spiral wound once. Curved waveguide 55 is disposed internal to curved waveguide 54. Curved waveguide 55 is disposed close to second end 58 with respect to curved waveguide 54. Curved waveguide 55 includes only one maximum curvature portion 55m. Maximum curvature portion 55m is a portion having a maximum curvature in curved waveguide 55. Curved waveguide 55 includes a curved waveguide portion 55a and a curved waveguide portion 55b.

Curved waveguide portion 55a is connected to curved waveguide portion 54b. Curved waveguide portion 55a is expanded toward the outside of substrate 10 (for example, in the +x direction (see FIG. 1)) in the plan view of main surface 10a of substrate 10. Curved waveguide portion 55a includes maximum curvature portion 55m. Curved waveguide portion 55b is connected to curved waveguide portion 55a. Curved waveguide portion 55b is disposed close to second end 58 with respect to curved waveguide portion 55a. Curved waveguide portion 55b is expanded toward the inside of substrate 10 (for example, in the −x direction (see FIG. 1)) in the plan view of main surface 10a of substrate 10. Curved waveguide portion 55b includes second end 58 of first termination waveguide 50.

In the plan view of main surface 10a of substrate 10 (plan view in the z direction as shown in FIGS. 1 and 6), a normal vector of curved waveguide 51 at maximum curvature portion 51m, a normal vector of curved waveguide 52 at maximum curvature portion 52m, a normal vector of curved waveguide 53 at maximum curvature portion 53m, a normal vector of curved waveguide 54 at maximum curvature portion 54m, and a normal vector of curved waveguide 55 at maximum curvature portion 55m are oriented in the same direction (for example, the +x direction). In the plan view of main surface 10a of substrate 10, the normal vector of curved waveguide 51 at maximum curvature portion 51m, the normal vector of curved waveguide 52 at maximum curvature portion 52m, the normal vector of curved waveguide 53 at maximum curvature portion 53m, the normal vector of curved waveguide 54 at maximum curvature portion 54m, and the normal vector of curved waveguide 55 at maximum curvature portion 55m are oriented toward the outside of substrate 10 (for example, the +x direction (see FIG. 1)).

In the present specification, a normal vector of a curved waveguide at a certain portion of a curved waveguide is defined as a vector that is perpendicular to a tangent of the curved waveguide at the certain portion and that extends from the certain portion in the expanding direction of the curved waveguide in the plan view of main surface 10a of substrate 10.

As shown in FIGS. 6 and 7, the curvature of maximum curvature portion 52m is larger than the curvature of maximum curvature portion 51m. The curvature of maximum curvature portion 53m is larger than the curvature of maximum curvature portion 52m. The curvature of maximum curvature portion 54m is larger than the curvature of maximum curvature portion 53m. The curvature of maximum curvature portion 55m is larger than the curvature of maximum curvature portion 54m. That is, the respective curvatures of maximum curvature portions 51m, 52m, 53m, 54m, 55m are larger as they are closer to second end 58 of first termination waveguide 50.

As shown in FIGS. 6 and 7, in the present embodiment, the curvature of each of curved waveguide portions 51a, 52a, 53a, 54a, 55a is changed linearly. The curvature of each of curved waveguide portions 51b, 52b, 53b, 54b, 55b is unchanged. However, the curvature of each of curved waveguide portions 51a, 52a, 53a, 54a, 55a may be changed in a non-curved manner. The curvature of each of curved waveguide portions 51b, 52b, 53b, 54b, 55b may be changed.

### (Operations and Functions of Optical Wavelength Filter 1 and Optical Terminator 30)

Operations and functions of optical wavelength filter 1 and optical terminator 30 according to the present embodiment will be described. It should be noted that each of optical terminators 31, 32, 33 operates in the same manner as optical terminator 30 and has the same function as that of optical terminator 30.

Light 40 enters optical wavelength filter 1 from the input port (end 11a of waveguide 11) of ring resonator 20. Light 42 (see FIG. 3) selected by ring resonator 20 in light 40 enters ring resonator 25. Light 46 selected by ring resonator 25 in light 42 enters mirror 35. Light 46 is reflected by mirror 35 and enters waveguide 16. Light 46 exits from end 16a of waveguide 16 to the outside of optical wavelength filter 1. Light 41 not selected by ring resonator 20 in light 40 is emitted as emission light 44 from optical terminator 30 to the outside of optical wavelength filter 1. The light not selected by ring resonator 25 in light 42 (see FIG. 3) is emitted as emission light from optical terminator 32 to the outside of optical wavelength filter 1.

Emission light 44 enters spectrum analyzer 48 through optical fiber 47. Spectrum analyzer 48 obtains the spectrum of emission light 44. Controller 49 controls the power to be supplied to refractive index regulator 21, based on the spectrum of emission light 44. For example, the power to be supplied to refractive index regulator 21 is regulated to attain a minimum spectral intensity of the wavelength, to be selected by optical wavelength filter 1, of emission light 44 from optical terminator 30. This leads to a maximum ratio of optical coupling, to the drop port of ring resonator 20, of the light having the wavelength to be selected by optical wavelength filter 1. The power to be supplied to refractive index regulator 26 is also controlled by controller 49 as with refractive index regulator 21. For example, the power to be supplied to refractive index regulator 26 is regulated based on the emission light emitted from optical terminator 32. In this way, the wavelength of light 46 to be output from optical wavelength filter 1 in light 40 having entered optical wavelength filter 1 can be tuned.

As shown in FIGS. 6 and 7, optical terminator 30 includes a plurality of curved waveguides 51, 52, 53, 54, 55. Therefore, light 41 (see FIG. 3) having entered optical terminator 30 from the through port (end 11b) of ring resonator 20 is repeatedly emitted from the plurality of curved waveguides 51, 52, 53, 54, 55. The intensity of emission light 44 is increased, and the intensity of the light to reach the terminal end (second end 58) of optical terminator 30 is decreased. Optical terminator 30 can further suppress reflection of light.

In optical terminator 30, in the plan view of main surface 10a of substrate 10 (plan view in the z direction as shown in FIGS. 1 and 6), the normal vector of curved waveguide 51 at maximum curvature portion 51m, the normal vector of curved waveguide 52 at maximum curvature portion 52m, the normal vector of curved waveguide 53 at maximum curvature portion 53m, the normal vector of curved waveguide 54 at maximum curvature portion 54m, and the normal vector of curved waveguide 55 at maximum curvature portion 55m are oriented in the same direction (for example, the +x direction). Therefore, the emission direction of the emission light from curved waveguide 51, the emission direction of the emission light from curved waveguide 52, the emission direction of the emission light from curved waveguide 53, the emission direction of the emission light from curved waveguide 54, and the emission direction of the emission light from curved waveguide 55 are the same. The directivity of emission light 44 emitted from optical terminator 30 can be improved.

In the plan view of main surface 10a of substrate 10, the normal vector of curved waveguide 51 at maximum curvature portion 51m, the normal vector of curved waveguide 52 at maximum curvature portion 52m, the normal vector of curved waveguide 53 at maximum curvature portion 53m, the normal vector of curved waveguide 54 at maximum curvature portion 54m, and the normal vector of curved waveguide 55 at maximum curvature portion 55m are oriented toward the outside of substrate 10 (for example, the +x direction (see FIG. 1)). Therefore, emission light 44 emitted from optical terminator 30 can be readily extracted to the outside of optical wavelength filter 1. The wavelength to be selected by ring resonator 20 can be readily tuned based on emission light 44.

The curvature of maximum curvature portion 52m is larger than the curvature of maximum curvature portion 51m. The curvature of maximum curvature portion 53m is larger than the curvature of maximum curvature portion 52m. The curvature of maximum curvature portion 54m is larger than the curvature of maximum curvature portion 53m. The curvature of maximum curvature portion 55m is larger than the curvature of maximum curvature portion 54m. Therefore, light not emitted from curved waveguide 51 can be emitted from curved waveguide 52 more efficiently. Light not emitted from curved waveguides 51, 52 can be emitted from curved waveguide 53 more efficiently. Light not emitted from curved waveguides 51, 52, 53 can be emitted from curved waveguide 54 more efficiently. Light not emitted from curved waveguides 51, 52, 53, 54 can be emitted from curved waveguide 55 more efficiently. Therefore, the intensity of emission light 44 is further increased, with the result that optical terminator 30 can further suppress reflection of light.

### Modification

Mirror 35 and waveguide 16 may be omitted and light 46 may exit from end 15a of waveguide 15 to the outside of optical wavelength filter 1.

When each of ring waveguides 12, 14 is composed of a material having an electro-optic effect (for example, a compound semiconductor material such as InGaAsP), refractive index regulators 21, 26 may be electrodes that can apply voltages to ring waveguides 12, 14.

The shape of spiral waveguide 50a is not limited to the shape of spiral wound five times and may be a shape of spiral wound multiple times.

Effects of optical terminator 30 and optical wavelength filter 1 according to the present embodiment will be described.

Optical terminator 30 according to the present embodiment includes: substrate 10 including main surface 10a; and first termination waveguide 50 formed on main surface 10a. First termination waveguide 50 includes first end 57, the first curved waveguide (for example, curved waveguide 51), the second curved waveguide (for example, curved waveguide 52), and second end 58 opposite to first end 57. The second curved waveguide is connected to the first curved waveguide and is disposed close to second end 58 with respect to the first curved waveguide. The first curved waveguide includes the only one first maximum curvature portion (for example, maximum curvature portion 51m). The first maximum curvature portion is a portion having a maximum curvature in the first curved waveguide. The second curved waveguide includes the only one second maximum curvature portion (for example, maximum curvature portion 52m). The second maximum curvature portion is a portion having a maximum curvature in the second curved waveguide. In the plan view of main surface 10a of substrate 10, the first normal vector of the first curved waveguide at the first maximum curvature portion and the second normal vector of the second curved waveguide at the second maximum curvature portion are oriented in the same direction.

Therefore, the light having entered optical terminator 30 is emitted from the first curved waveguide (for example, curved waveguide 51) and the second curved waveguide (for example, curved waveguide 52). The intensity of emission light 44 from first termination waveguide 50 is increased, and the intensity of the light to reach the terminal end (second end 58) of optical terminator 30 is decreased. Optical terminator 30 can further suppress reflection of light. Further, since the first normal vector and the second normal vector are oriented in the same direction, the directivity of emission light 44 emitted from optical terminator 30 can be improved.

In optical terminator 30 according to the present embodiment, in the plan view of main surface 10a of substrate 10, the first normal vector and the second normal vector are oriented toward outside of substrate 10.

Therefore, emission light 44 emitted from optical terminator 30 can be readily extracted to the outside of substrate 10.

In optical terminator 30 according to the present embodiment, the first curved waveguide (for example, curved waveguide 51) includes the first curved waveguide portion (for example, curved waveguide portion 51a) expanded toward the outside of substrate 10 in the plan view of main surface 10a of substrate 10, and the second curved waveguide portion (for example, curved waveguide portion 51b) expanded toward the inside of substrate 10 in the plan view of main surface 10a of substrate 10. The second curved waveguide (for example, curved waveguide 52) includes the third curved waveguide portion (for example, curved waveguide portion 52a) expanded toward the outside of substrate 10 in the plan view of main surface 10a of substrate 10, and the fourth curved waveguide portion (for example, curved waveguide portion 52b) expanded toward the inside of substrate 10 in the plan view of main surface 10a of substrate 10. The first curved waveguide portion includes the first maximum curvature portion (for example, maximum curvature portion 51m). The third curved waveguide portion includes the second maximum curvature portion (for example, maximum curvature portion 52m).

Therefore, emission light 44 emitted from optical terminator 30 can be readily extracted to the outside of substrate 10.

In optical terminator 30 according to the present embodiment, the second curvature of the second maximum curvature portion (for example, maximum curvature portion 52m) is larger than the first curvature of the first maximum curvature portion (for example, maximum curvature portion 51m).

Therefore, light not emitted from the first curved waveguide (for example, curved waveguide 51) can be emitted from the second curved waveguide (for example, curved waveguide 52) more efficiently. Optical terminator 30 can further suppress reflection of light.

In optical terminator 30 according to the present embodiment, in the plan view of main surface 10a of substrate 10, first termination waveguide 50 is spiral waveguide 50a.

Therefore, optical terminator 30 can further suppress reflection of light. The directivity of emission light 44 emitted from optical terminator 30 can be improved.

Optical wavelength filter 1 according to the present embodiment includes: optical terminator 30 according to the present embodiment; ring resonator 20; and refractive index regulator 21. Ring resonator 20 is connected to first end 57. Refractive index regulator 21 regulates the refractive index of ring resonator 20.

Emission light 44 from optical terminator 30 has higher intensity and higher directivity. Therefore, the wavelength of the light to be selected by optical wavelength filter 1 can be more precisely tuned based on emission light 44 from optical terminator 30.

### Second Embodiment

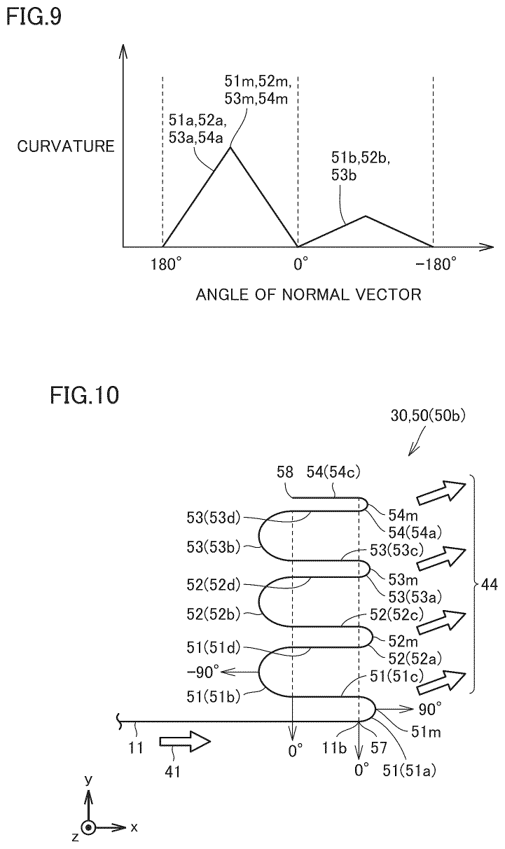

An optical wavelength filter 1 according to a second embodiment will be described with reference to FIGS. 1, 8, and 9. Optical wavelength filter 1 according to the present embodiment has the same configuration and effect as those of optical wavelength filter 1 according to the first embodiment, but is different from optical wavelength filter 1 according to the first embodiment in terms of optical terminators 30, 31, 32, 33. Also in optical wavelength filter 1 according to the present embodiment, each of optical terminators 31, 32, 33 is configured in the same manner as optical terminator 30 and functions in the same manner as optical terminator 30. Therefore, optical terminator 30 according to the present embodiment will be described in detail with reference to FIGS. 8 and 9.

In the present embodiment, in the plan view of main surface 10a of substrate 10 (plan view in the z direction as shown in FIGS. 1 and 8), first termination waveguide 50 is a first meandering waveguide 50b. A meandering direction of first meandering waveguide 50b is the x direction, and a meander-proceeding direction of first meandering waveguide 50b is the +y direction. First meandering waveguide 50b meanders seven times. First termination waveguide 50 includes a first end 57, curved waveguides 51, 52, 53, 54, and a second end 58 opposite to first end 57.

First end 57 of first termination waveguide 50 is connected to end 11b of waveguide 11, which is the through port of ring resonator 20. First end 57 is the optical input end of optical terminator 30. Second end 58 is the terminal end of optical terminator 30.

Curved waveguide 51 includes first end 57 of first termination waveguide 50 and is connected to end 11b of waveguide 11. Curved waveguide 51 meanders twice. Curved waveguide 51 includes only one maximum curvature portion 51m. Maximum curvature portion 51m is a portion having a maximum curvature in curved waveguide 51. Curved waveguide 51 includes a curved waveguide portion 51a, a curved waveguide portion 51b, a straight waveguide portion 51c, and a straight waveguide portion 51d.

Curved waveguide portion 51a is connected to waveguide 11 and includes first end 57 of first termination waveguide 50. Curved waveguide portion 51a meanders once. Curved waveguide portion 51a is expanded toward the outside of substrate 10 (for example, in the +x direction (see FIG. 1)) in the plan view of main surface 10a of substrate 10. Curved waveguide portion 51a includes maximum curvature portion 51m. Straight waveguide portion 51c is connected to curved waveguide portion 51a. Straight waveguide portion 51c is disposed close to second end 58 with respect to curved waveguide portion 51a. Straight waveguide portion 51c extends in a direction (x direction) perpendicular to the meander-proceeding direction of first meandering waveguide 50b.

Curved waveguide portion 51b is connected to straight waveguide portion 51c. Curved waveguide portion 51b is disposed close to second end 58 with respect to straight waveguide portion 51c. Curved waveguide portion 51b meanders once. Curved waveguide portion 51b is expanded toward the inside of substrate 10 (for example, in the −x direction (see FIG. 1)) in the plan view of main surface 10a of substrate 10. Straight waveguide portion 51d is connected to curved waveguide portion 51b. Straight waveguide portion 51d is disposed close to second end 58 with respect to curved waveguide portion 51b. Straight waveguide portion 51d extends in the direction (x direction) perpendicular to the meander-proceeding direction of first meandering waveguide 50b.

Curved waveguide 52 is connected to curved waveguide 51. Curved waveguide 52 is disposed on a side (+y side) opposite to waveguide 11 with respect to curved waveguide 51. Curved waveguide 52 is disposed close to second end 58 with respect to curved waveguide 51. Curved waveguide 52 meanders twice. Curved waveguide 52 includes only one maximum curvature portion 52m. Maximum curvature portion 52m is a portion having a maximum curvature in curved waveguide 52. Curved waveguide 52 includes a curved waveguide portion 52a, a curved waveguide portion 52b, a straight waveguide portion 52c, and a straight waveguide portion 52d.

Curved waveguide portion 52a is connected to straight waveguide portion 51d. Curved waveguide portion 52a meanders once. Curved waveguide portion 52a is expanded toward the outside of substrate 10 (for example, in the +x direction (see FIG. 1)) in the plan view of main surface 10a of substrate 10. Curved waveguide portion 52a includes maximum curvature portion 52m. Straight waveguide portion 52c is connected to curved waveguide portion 52a. Straight waveguide portion 52c is disposed close to second end 58 with respect to curved waveguide portion 52a. Straight waveguide portion 52c extends in the direction (x direction) perpendicular to the meander-proceeding direction of first meandering waveguide 50b.

Curved waveguide portion 52b is connected to straight waveguide portion 52c. Curved waveguide portion 52b is disposed close to second end 58 with respect to straight waveguide portion 52c. Curved waveguide portion 52b meanders once. Curved waveguide portion 52b is expanded toward the inside of substrate 10 (for example, in the −x direction (see FIG. 1)) in the plan view of main surface 10a of substrate 10. Straight waveguide portion 52d is connected to curved waveguide portion 52b. Straight waveguide portion 52d is disposed close to second end 58 with respect to curved waveguide portion 52b. Straight waveguide portion 52d extends in the direction (x direction) perpendicular to the meander-proceeding direction of first meandering waveguide 50b.

Curved waveguide 53 is connected to curved waveguide 52. Curved waveguide 53 is disposed on the side (+y side) opposite to waveguide 11 with respect to curved waveguide 52. Curved waveguide 53 is disposed close to second end 58 with respect to curved waveguide 52. Curved waveguide 53 meanders twice. Curved waveguide 53 includes only one maximum curvature portion 53m. Maximum curvature portion 53m is a portion having a maximum curvature in curved waveguide 53. Curved waveguide 53 includes a curved waveguide portion 53a, a curved waveguide portion 53b, a straight waveguide portion 53c, and a straight waveguide portion 53d.

Curved waveguide portion 53a is connected to straight waveguide portion 52d. Curved waveguide portion 53a meanders once. Curved waveguide portion 53a is expanded toward the outside of substrate 10 (for example, in the +x direction (see FIG. 1)) in the plan view of main surface 10a of substrate 10. Curved waveguide portion 53a includes maximum curvature portion 53m. Straight waveguide portion 53c is connected to curved waveguide portion 53a. Straight waveguide portion 53c is disposed close to second end 58 with respect to curved waveguide portion 53a. Straight waveguide portion 53c extends in the direction (x direction) perpendicular to the meander-proceeding direction of first meandering waveguide 50b.

Curved waveguide portion 53b is connected to straight waveguide portion 52d. Curved waveguide portion 53b is disposed close to second end 58 with respect to straight waveguide portion 53c. Curved waveguide portion 53b meanders once. Curved waveguide portion 53b is expanded toward the inside of substrate 10 (for example, in the −x direction (see FIG. 1)) in the plan view of main surface 10a of substrate 10. Straight waveguide portion 53d is connected to curved waveguide portion 53b. Straight waveguide portion 53d is disposed close to second end 58 with respect to curved waveguide portion 53b. Straight waveguide portion 53d extends in the direction (x direction) perpendicular to the meander-proceeding direction of first meandering waveguide 50b.

Curved waveguide 54 is connected to curved waveguide 53. Curved waveguide 54 is disposed on the side (+y side) opposite to waveguide 11 with respect to curved waveguide 53. Curved waveguide 54 is disposed close to second end 58 with respect to curved waveguide 53. Curved waveguide 54 meanders once. Curved waveguide 54 includes only one maximum curvature portion 54m. Maximum curvature portion 54m is a portion having a maximum curvature in curved waveguide 54. Curved waveguide 54 includes a curved waveguide portion 54a, a curved waveguide portion 54b, and a straight waveguide portion 54c.

Curved waveguide portion 54a is connected to straight waveguide portion 53d. Curved waveguide portion 54a meanders once. Curved waveguide portion 54a is expanded toward the outside of substrate 10 (for example, in the +x direction (see FIG. 1)) in the plan view of main surface 10a of substrate 10. Curved waveguide portion 54a includes maximum curvature portion 54m. Straight waveguide portion 54c is connected to curved waveguide portion 54a. Straight waveguide portion 54c is disposed close to second end 58 with respect to curved waveguide portion 54a. Straight waveguide portion 54c extends in the direction (x direction) perpendicular to the meander-proceeding direction of first meandering waveguide 50b. Straight waveguide portion 54c includes second end 58 of first termination waveguide 50.

In the plan view of main surface 10a of substrate 10 (plan view in the z direction as shown in FIGS. 1 and 8), a normal vector of curved waveguide 51 at maximum curvature portion 51m, a normal vector of curved waveguide 52 at maximum curvature portion 52m, a normal vector of curved waveguide 53 at the maximum curvature portion 53m, and a normal vector of curved waveguide 54 at maximum curvature portion 54m are oriented in the same direction (for example, the +x direction). In the plan view of main surface 10a of substrate 10, the normal vector of curved waveguide 51 at maximum curvature portion 51m, the normal vector of curved waveguide 52 at maximum curvature portion 52m, the normal vector of curved waveguide 53 at maximum curvature portion 53m, and the normal vector of curved waveguide 54 at maximum curvature portion 54m are oriented toward the outside of substrate 10 (for example, the +x direction (see FIG. 1)).

As shown in FIGS. 8 and 9, the curvature of maximum curvature portion 51m, the curvature of maximum curvature portion 52m, the curvature of maximum curvature portion 53m, and the curvature of maximum curvature portion 54m are equal to one another.

As shown in FIGS. 8 and 9, in the present embodiment, the curvature of each of curved waveguide portions 51a, 52a, 53a, 54a is changed linearly. The curvature of each of curved waveguide portions 51b, 52b, 53b is changed linearly. However, the curvature of each of curved waveguide portions 51a, 52a, 53a, 54a can be changed in a non-curved manner. The curvature of each of curved waveguide portions 51b, 52b, 53b can be changed in a non-curved manner or may be unchanged.

Optical terminator 30 according to the present embodiment has the same function as that of the optical terminator 30 according to the first embodiment. It should be noted that each of optical terminators 31, 32, 33 also has the same function as that of optical terminator 30.

Specifically, as shown in FIGS. 8 and 9, optical terminator 30 includes the plurality of curved waveguides 51, 52, 53, 54. Therefore, light 41 (see FIG. 3) having entered optical terminator 30 is repeatedly emitted from the plurality of curved waveguides 51, 52, 53, 54. The intensity of emission light 44 is increased, and the intensity of the light to reach the terminal end (second end 58) of optical terminator 30 is decreased. Optical terminator 30 can further suppress reflection of light.

In optical terminator 30, in the plan view of main surface 10a of substrate 10 (plan view in the z direction as shown in FIGS. 1 and 8), the normal vector of curved waveguide 51 at maximum curvature portion 51m, the normal vector of curved waveguide 52 at maximum curvature portion 52m, the normal vector of curved waveguide 53 at maximum curvature portion 53m, and the normal vector of curved waveguide 54 at maximum curvature portion 54m are oriented in the same direction (for example, the +x direction). Therefore, the emission direction of the emission light from curved waveguide 51, the emission direction of the emission light from curved waveguide 52, the emission direction of the emission light from curved waveguide 53, and the emission direction of the emission light from curved waveguide 54 are the same. The directivity of emission light 44 emitted from optical terminator 30 can be improved.

In the plan view of main surface 10a of substrate 10, the normal vector of curved waveguide 51 at maximum curvature portion 51m, the normal vector of curved waveguide 52 at maximum curvature portion 52m, the normal vector of curved waveguide 53 at maximum curvature portion 53m, and the normal vector of curved waveguide 54 at maximum curvature portion 54m are oriented toward the outside of substrate 10 (for example, the +x direction (see FIG. 1)). Therefore, emission light 44 emitted from optical terminator 30 can be readily extracted to the outside of optical wavelength filter 1. The wavelength to be selected by ring resonator 20 can be readily tuned based on emission light 44.

### Modification

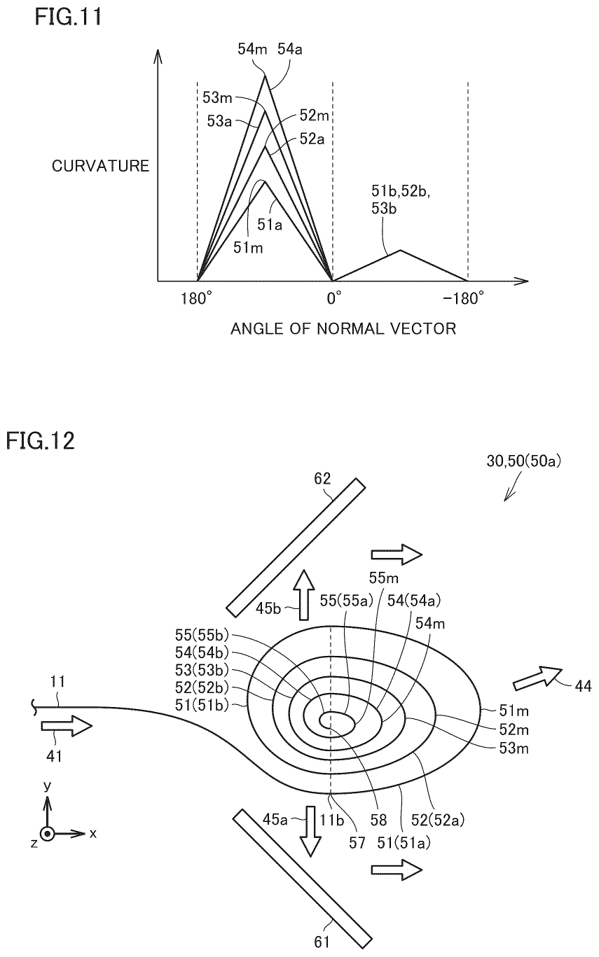

Referring to FIGS. 10 and 11, in a modification of the present embodiment, the curvature of maximum curvature portion 52m is larger than the curvature of maximum curvature portion 51m. The curvature of maximum curvature portion 53m is larger than the curvature of maximum curvature portion 52m. The curvature of maximum curvature portion 54m is larger than the curvature of maximum curvature portion 53m. That is, the respective curvatures of maximum curvature portions 51m, 52m, 53m, 54m are larger as they are closer to second end 58 of first termination waveguide 50. Therefore, light not emitted from curved waveguide 51 can be emitted from curved waveguide 52 more efficiently. Light not emitted from curved waveguides 51, 52 can be emitted from curved waveguide 53 more efficiently. Light not emitted from curved waveguides 51, 52, 53 can be emitted from curved waveguide 54 more efficiently. In the modification of the present embodiment, reflection of light in optical terminator 30 can be further suppressed.

Straight waveguide portions 51c, 51d, 52c, 52d, 53c, 53d, 54c may be omitted from first termination waveguide 50.

Optical terminator 30 according to the present embodiment has the following effect similar to that of optical terminator 30 according to the first embodiment. Optical wavelength filter 1 according to the present embodiment has an effect similar to that of optical wavelength filter 1 according to the first embodiment.

In optical terminator 30 according to the present embodiment, in the plan view of main surface 10a of substrate 10, first termination waveguide 50 is first meandering waveguide 50b.

Therefore, optical terminator 30 can further suppress reflection of light. The directivity of emission light 44 emitted from optical terminator 30 can be improved.

### Third Embodiment

An optical wavelength filter 1 according to a third embodiment will be described with reference to FIGS. 1 and 12. Optical wavelength filter 1 according to the present embodiment has the same configuration and effect as those of optical wavelength filter 1 according to the first embodiment, but is different from optical wavelength filter 1 according to the first embodiment in terms of optical terminators 30, 31, 32, 33. Also in optical wavelength filter 1 according to the present embodiment, each of optical terminators 31, 32, 33 is configured in the same manner as optical terminator 30 and functions in the same manner as optical terminator 30. Therefore, optical terminator 30 according to the present embodiment will be described in detail with reference to FIG. 12.

Optical terminator 30 according to the present embodiment further includes reflection elements 61, 62. Reflection elements 61, 62 are, for example, reflection grooves formed in the cladding layers (upper cladding layer 18 and lower cladding layer 17). Reflection elements 61, 62 are disposed away from first termination waveguide 50. Reflection elements 61, 62 reflect leakage light 45a and leakage light 45b each leaked from first termination waveguide 50 and traveling in a direction different from the direction of emission light 44, so as to direct leakage light 45a and leakage light 45b in the same direction as the direction of emission light 44 (for example, toward the outside of substrate 10 (for example, the +x direction (see FIG. 1))). Each of leakage light 45a and leakage light 45b becomes a part of emission light 44.

Each of reflection elements 61, 62 is disposed, for example, in the direction (y direction) perpendicular to the direction (+x direction) of the normal vector of each of maximum curvature portions 51m, 52m, 53m, 54m, 55m with respect to first termination waveguide 50. For example, reflection element 61 is disposed in the −y direction with respect to first termination waveguide 50. Reflection element 62 is disposed in the +y direction with respect to first termination waveguide 50. Each of reflection elements 61, 62 may face curved waveguide portion 51b.

### Modification

Optical terminator 30 may include at least one reflection element.

Each of reflection elements 61, 62 may be disposed in the direction (−x direction) opposite to the direction (+x direction) of the normal vector of each of maximum curvature portions 51m, 52m, 53m, 54m, 55m with respect to first termination waveguide 50, for example.

As with the present embodiment, at least one reflection element (for example, reflection elements 61, 62) may be provided in each of first termination waveguides 50 (see FIGS. 8 and 10) according to the second embodiment and the modification thereof.

Optical terminator 30 and optical wavelength filter 1 according to the present embodiment have the following effects in addition to the effects of optical terminator 30 and optical wavelength filter 1 according to the first embodiment.

Optical terminator 30 according to the present embodiment further includes reflection elements 61, 62 each disposed away from first termination waveguide 50. Reflection elements 61, 62 reflect leakage light 45a and leakage light 45b from first termination waveguide 50 to direct leakage light 45a and leakage light 45b toward the outside of substrate 10.

Therefore, the intensity of emission light 44 emitted from optical terminator 30 is improved. Based on emission light 44 from optical terminator 30, the wavelength of the light to be selected by optical wavelength filter 1 can be more precisely tuned.

### Fourth Embodiment

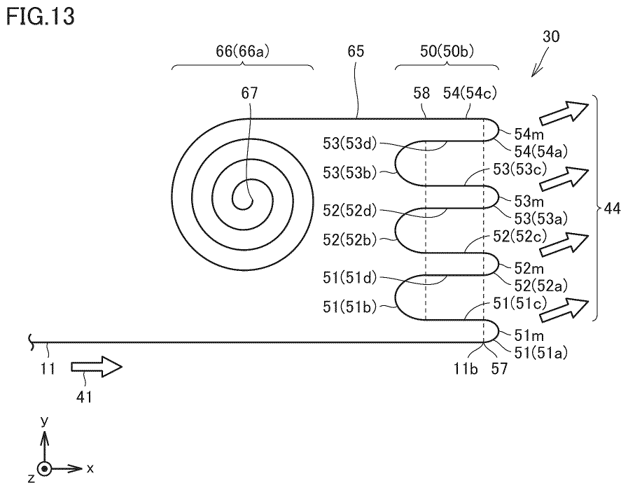

An optical wavelength filter 1 according to a fourth embodiment will be described with reference to FIGS. 1 and 13. Optical wavelength filter 1 according to the present embodiment has the same configuration and effect as those of optical wavelength filter 1 according to the second embodiment (see FIGS. 1, 8, and 9), but is different from optical wavelength filter 1 according to the second embodiment in terms of optical terminators 30, 31, 32, 33. Also in optical wavelength filter 1 according to the present embodiment, each of optical terminators 31, 32, 33 is configured in the same manner as optical terminator 30 and functions in the same manner as optical terminator 30. Therefore, optical terminator 30 according to the present embodiment will be described in detail with reference to FIG. 13.

Optical terminator 30 according to the present embodiment further includes a second termination waveguide 66. Second termination waveguide 66 is connected to second end 58 of first termination waveguide 50. The expression “second termination waveguide 66 is connected to second end 58 of first termination waveguide 50” means that second termination waveguide 66 is directly connected to second end 58 of first termination waveguide 50 or means that second termination waveguide 66 is connected to second end 58 of first termination waveguide 50 via a straight waveguide portion 65. In the plan view of main surface 10a of substrate 10 (plan view in the z direction as shown in FIGS. 1 and 13), second termination waveguide 66 is a spiral waveguide 66a. Terminal end 67 of second termination waveguide 66 is the terminal end of optical terminator 30.

Second termination waveguide 66 faces waveguide 11 in the meander-proceeding direction (+y direction) of first meandering waveguide 50b. Second termination waveguide 66 faces first meandering waveguide 50b in the meandering direction (x direction) of first meandering waveguide 50b. More specifically, second termination waveguide 66 faces at least one of curved waveguide portions 51b, 52b, 53b in the meandering direction (x direction) of first meandering waveguide 50b. Second termination waveguide 66 is disposed at the same position as second end 58 of first termination waveguide 50 in the meander-proceeding direction (+y direction) of first meandering waveguide 50b, or is disposed on a side (−y side) opposite to the meander-proceeding direction (+y direction) of first meandering waveguide 50b with respect to second end 58 of first termination waveguide 50. Second termination waveguide 66 is not disposed on the side (+y side) of the meander-proceeding direction of first meandering waveguide 50b with respect to second end 58 of first termination waveguide 50.

### Modification

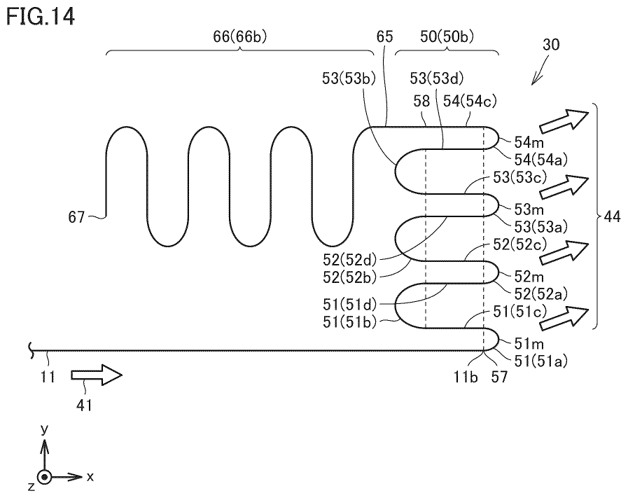

Referring to FIG. 14, in the modification of the present embodiment, in the plan view of main surface 10a of substrate 10, second termination waveguide 66 is a second meandering waveguide 66b. A meandering direction of second meandering waveguide 66b is, for example, along the meander-proceeding direction (+y direction) of first meandering waveguide 50b. Specifically, the meandering direction of second meandering waveguide 66b is the y direction. A meander-proceeding direction of second meandering waveguide 66b is, for example, along the meandering direction (x direction) of first meandering waveguide 50b. Specifically, the meander-proceeding direction of second meandering waveguide 66b is the −x direction. The meander-proceeding direction of second meandering waveguide 66b is, for example, opposite to the direction of the normal vector of first meandering waveguide 50b at each of maximum curvature portions 51m, 52m, 53m, 54m.

Optical terminator 30 according to the present embodiment has the following effect in addition to the effect of optical terminator 30 according to the first embodiment.

Optical terminator 30 according to the present embodiment further includes second termination waveguide 66 connected to second end 58. Second termination waveguide 66 faces first meandering waveguide 50b in the meandering direction of first meandering waveguide 50b.

Therefore, the light having entered optical terminator 30 is emitted from not only first termination waveguide 50 but also second termination waveguide 66. The intensity of the light to reach the terminal end (terminal end 67) of optical terminator 30 is further reduced. Optical terminator 30 can further suppress reflection of light. Further, since second termination waveguide 66 faces first meandering waveguide 50b in the meandering direction of first meandering waveguide 50b, the size of optical terminator 30 can be reduced.

In optical terminator 30 according to the present embodiment, in the plan view of main surface 10a of substrate 10, second termination waveguide 66 is spiral waveguide 66a.

Therefore, the intensity of the light to reach the terminal end (terminal end 67) of optical terminator 30 is further reduced. Optical terminator 30 can further suppress reflection of light. The size of optical terminator 30 can be reduced.

In optical terminator 30 according to the present embodiment, in the plan view of main surface 10a of substrate 10, second termination waveguide 66 is second meandering waveguide 66b.

Therefore, the intensity of the light to reach the terminal end (terminal end 67) of optical terminator 30 is further reduced. Optical terminator 30 can further suppress reflection of light. The size of optical terminator 30 can be reduced.

### Fifth Embodiment

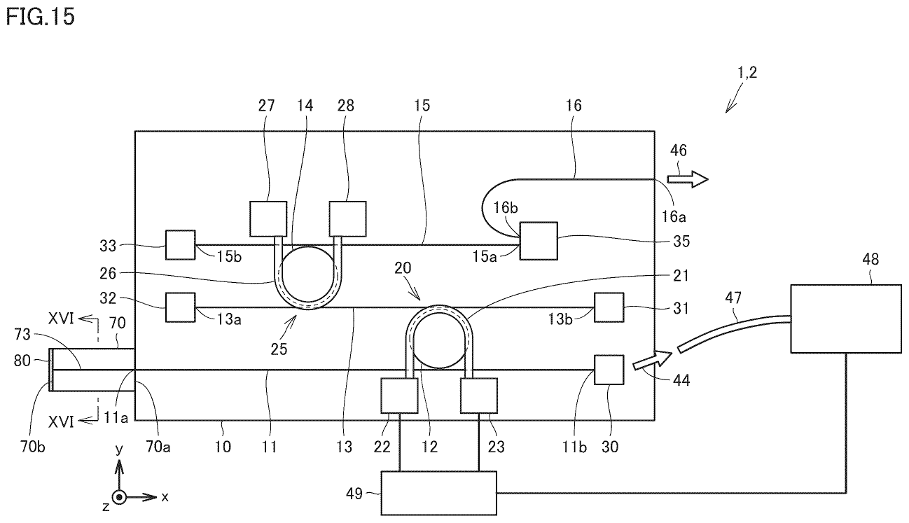

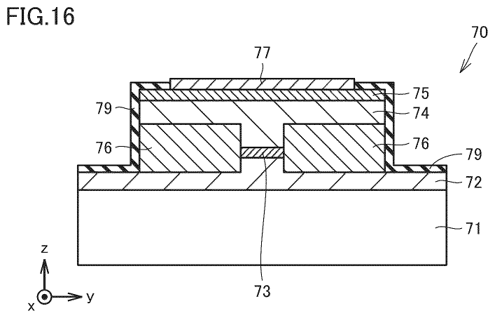

An external cavity laser light source 2 according to a fifth embodiment will be described with reference to FIGS. 15 and 16. External cavity laser light source 2 according to the present embodiment includes optical wavelength filter 1 according to the first embodiment, an optical amplifier 70, and a mirror 80.

As shown in FIG. 16, optical amplifier 70 is, for example, a semiconductor optical amplifier (SOA). Specifically, optical amplifier 70 includes a semiconductor substrate 71, a lower cladding layer 72, an active layer 73, an upper cladding layer 74, a contact layer 75, current blocking layers 76, an electrode 77, and an insulating protective film 79.

Semiconductor substrate 71 is composed of a semiconductor material such as InP. Lower cladding layer 72 is formed on semiconductor substrate 71. Lower cladding layer 72 is, for example, an n type semiconductor layer. Lower cladding layer 72 is, for example, an n type InP layer.

Active layer 73 is formed on lower cladding layer 72. Active layer 73 has a smaller band gap energy than that of each of lower cladding layer 72 and upper cladding layer 74, and has a higher refractive index than that of each of lower cladding layer 72 and upper cladding layer 74. Active layer 73 is, for example, a multi-quantum well (MQW) layer composed of AlGaInAs.

Upper cladding layer 74 is formed on active layer 73. Upper cladding layer 74 has a conductivity type opposite to that of lower cladding layer 72. Upper cladding layer 74 is, for example, a p type semiconductor layer. Upper cladding layer 74 is, for example, a p type InP layer. Contact layer 75 is formed on upper cladding layer 74. Contact layer 75 is a semiconductor layer having the same conductivity type as that of upper cladding layer 74 and having a lower resistance than that of upper cladding layer 74. Contact layer 75 is, for example, a p type InGaAs layer.

Electrode 77 is formed on contact layer 75. Electrode 77 is a single-layer metal layer or multi-layer metal layer each composed of a metal material such as Ti, Au, Pt, Nb, or Ni. A current is injected from electrode 77 into active layer 73. Light, which is amplified spontaneous emission (ASE), is emitted from active layer 73. The light reflected by mirror 35 and mirror 80 is amplified in active layer 73.

Current blocking layers 76 are disposed on both sides beside active layer 73. Current blocking layers 76 the current injected from electrode 77 does not flow through current blocking layers 76 and flows into active layer 73 in a concentrated manner. Each of current blocking layers 76 diffuses heat generated in active layer 73. Therefore, gain of active layer 73 can be suppressed from being decreased due to an increase in the temperature of active layer 73. Current blocking layer 76 is, for example, a semi-insulating semiconductor layer such as an Fe-doped InP layer, or is a semiconductor stack in which a p type semiconductor layer and an n type semiconductor layer are alternately stacked.

Insulating protective film 79 covers outer surfaces of the semiconductor layers (for example, lower cladding layer 72, active layer 73, upper cladding layer 74, contact layer 75, and current blocking layer 76) included in optical amplifier 70. Insulating protective film 79 prevents each of the semiconductor layers included in optical amplifier 70 from being oxidized or altered due to moisture or oxygen contained in an atmosphere around optical amplifier 70. Insulating protective film 79 is composed of, for example, an inorganic oxide film such as SiO₂, an inorganic nitride film such as SiN, or an organic insulating film such as benzocyclobutene (BCB).

As shown in FIG. 16, optical amplifier 70 includes an end surface 70a and an end surface 70b opposite to end surface 70a. End surface 70a faces end 11a of waveguide 11, which is the entrance end of optical wavelength filter 1. Optical amplifier 70 is optically coupled to end 11a of waveguide 11. End surface 70b faces mirror 80. Mirror 35 and mirror 80 form an external resonator in external cavity laser light source 2. Optical amplifier 70 and ring resonators 20, 25 are disposed between mirror 35 and mirror 80.

The operation of external cavity laser light source 2 will be described. When a current is injected into active layer 73 from electrode 77, amplified spontaneous emission (ASE) is emitted from active layer 73. The light emitted from active layer 73 is coupled to waveguide 11, is reflected by mirror 35 and mirror 80, and is resonated between mirror 35 and mirror 80. In the light emitted from active layer 73, light having a wavelength to be selected by optical wavelength filter 1 is amplified by optical amplifier 70. External cavity laser light source 2 outputs light 46 as laser light from end 16a of waveguide 16.

### (Function)

Since external cavity laser light source 2 includes optical terminators 30, 31, 32, 33, reflected return light to enter optical amplifier 70 is reduced. Optical terminators 30, 31, 32, 33 can stabilize laser oscillation of external cavity laser light source 2. In order to operate external cavity laser light source 2, optical amplifier 70 needs to be precisely aligned with optical wavelength filter 1 and the wavelength to be selected by each of ring resonators 20, 25 needs to be appropriately set. However, before optical amplifier 70 is precisely aligned with optical wavelength filter 1 or before the wavelength to be selected by each of ring resonators 20, 25 is appropriately set, external cavity laser light source 2 does not perform laser oscillation and light 46 output from the output end (end 16a) of optical wavelength filter 1 is extremely weak. Therefore, the alignment of optical amplifier 70 with optical wavelength filter 1 and the setting of the wavelength to be selected by each of ring resonators 20, 25 cannot be performed using light 46.

To address this, in the present embodiment, emission light 44 having higher intensity and higher directivity is emitted from optical terminator 30. Before optical amplifier 70 is precisely aligned with optical wavelength filter 1 or before the wavelength to be selected by each of ring resonators 20, 25 is appropriately set, the intensity of emission light 44 emitted from optical terminator 30 is larger than the intensity of light 46. As with emission light 44, the intensity of the emission light emitted from optical terminator 32 is also larger than the intensity of light 46. Therefore, based on emission light 44 emitted from optical terminator 30, optical amplifier 70 can be precisely aligned with optical wavelength filter 1 and the wavelength to be selected by ring resonator 20 can be appropriately set. The wavelength to be selected by ring resonator 25 can be appropriately set based on the emission light emitted from optical terminator 32.

Specifically, when a current is injected into active layer 73 from electrode 77, amplified spontaneous emission (ASE light) is output from active layer 73. The ASE light has, for example, a wavelength band of about 50 nm. Light, in the ASE light, with a wavelength other than the wavelength of the light coupled to each of ring resonators 20, 25 is emitted as emission light 44 from optical terminator 30 or is emitted as the emission light from optical terminator 32. When optical amplifier 70 is precisely aligned with optical wavelength filter 1, the intensity of emission light 44 emitted from optical terminator 30 is maximum. Therefore, optical amplifier 70 is precisely aligned with optical wavelength filter 1 by moving optical amplifier 70 with respect to optical wavelength filter 1 so as to attain the maximum intensity of emission light 44.

Then, as described in the first embodiment, the current to be supplied to refractive index regulator 21 is regulated to attain the minimum spectral intensity of the wavelength, to be selected by optical wavelength filter 1, of emission light 44 from optical terminator 30. The current to be supplied to refractive index regulator 26 is regulated to attain the minimum spectral intensity of the wavelength, to be selected by optical wavelength filter 1, of the emission light from optical terminator 32. In this way, the wavelength to be selected by each of ring resonators 20, 25 can be precisely set, and the wavelength to be selected by optical wavelength filter 1 can be precisely set.

### Modification

External cavity laser light source 2 may include any one of optical wavelength filters 1 according to the second to fourth embodiments instead of optical wavelength filter 1 according to the first embodiment.

An effect of external cavity laser light source 2 according to the present embodiment will be described.

External cavity laser light source 2 according to the present embodiment includes: optical wavelength filter 1; and optical amplifier 70 optically coupled to ring resonator 20.

Therefore, the alignment of optical amplifier 70 with optical wavelength filter 1 and the setting of the wavelength to be selected by optical wavelength filter 1 can be performed more precisely by using the emission light emitted from each of optical terminators 30, 32 without laser oscillation of the external cavity laser light source 2.

The first to fifth embodiments and modifications thereof disclosed herein are illustrative and non-restrictive in any respect. As long as there is no contradiction, at least two of the first to fifth embodiments and the modifications thereof disclosed herein may be combined. The scope of the present disclosure is defined by the terms of the claims, rather than the embodiments described above, and is intended to include any modifications within the scope and meaning equivalent to the terms of the claims.

### REFERENCE SIGNS LIST

1: optical wavelength filter; 2: external cavity laser light source; 10: substrate; 10a: main surface; 11, 13, 15, 16: waveguide; 11a, 11b, 13a, 13b, 15a, 15b, 16a, 16b: end; 12, 14: ring waveguide; 17: lower cladding layer; 18: upper cladding layer; 20, 25: ring resonator; 21, 26: refractive index regulator; 22, 23, 27, 28: electrode pad; 30, 31, 32, 33: optical terminator; 35, 80: mirror; 40, 41, 42, 46: light; 44: emission light; 45a, 45b: leakage light; 47: optical fiber; 48: spectrum analyzer; 49: controller; 50: first termination waveguide; 50a: spiral waveguide; 50b: first meandering waveguide; 51, 52, 53, 54, 55: curved waveguide; 51a, 51b, 52a, 52b, 53a, 53b, 54a, 54b, 55a, 55b: curved waveguide portion; 51c, 51d, 52c, 52d, 53c, 53d, 54c, 65: straight waveguide portion; 51m, 52m, 53m, 54m, 55m: maximum curvature portion; 57: first end; 58: second end; 61, 62: reflection element; 66: second termination waveguide; 66a: spiral waveguide; 66b: second meandering waveguide; 67: terminal end; 70: optical amplifier; 70a, 70b: end surface; 71: semiconductor substrate; 72: lower cladding layer; 73: active layer; 74: upper cladding layer; 75: contact layer; 76: current blocking layer; 77: electrode; 79: insulating protective film.

1. An optical terminator comprising:
a substrate including a main surface; and
a first termination waveguide formed on the main surface, wherein
the first termination waveguide includes a first end, a first curved waveguide, a second curved waveguide, and a second end opposite to the first end,
in a plan view of the main surface, normal vectors of the first curved waveguide are oriented in all directions,
the second curved waveguide is connected to the first curved waveguide and is disposed close to the second end with respect to the first curved waveguide,
in the plan view of the main surface, normal vectors of the second curved waveguide are oriented in the all directions,
the first curved waveguide includes only one first maximum curvature portion at a portion of the first curved waveguide other than both ends of the first curved waveguide, and the first maximum curvature portion is a portion having a maximum curvature in the first curved waveguide,
the second curved waveguide includes only one second maximum curvature portion at a portion of the second curved waveguide other than both ends of the second curved waveguide, and the second maximum curvature portion is a portion having a maximum curvature in the second curved waveguide, and
in the plan view of the main surface, a first normal vector of the first curved waveguide at the first maximum curvature portion and a second normal vector of the second curved waveguide at the second maximum curvature portion are oriented in the same direction.

2. The optical terminator according to claim 1, wherein in the plan view of the main surface, the first normal vector and the second normal vector are oriented toward outside of the substrate.

3. The optical terminator according to claim 1, wherein
the first curved waveguide includes a first curved waveguide portion expanded toward outside of the substrate in the plan view of the main surface, and a second curved waveguide portion expanded toward inside of the substrate in the plan view of the main surface,
the second curved waveguide includes a third curved waveguide portion expanded toward the outside of the substrate in the plan view of the main surface, and a fourth curved waveguide portion expanded toward the inside of the substrate in the plan view of the main surface,
the first curved waveguide portion includes the first maximum curvature portion, and
the third curved waveguide portion includes the second maximum curvature portion.

4. The optical terminator according to claim 2, further comprising a reflection element disposed away from the first termination waveguide, wherein
the reflection element reflects leakage light from the first termination waveguide to direct the leakage light toward the outside of the substrate.

5. The optical terminator according to claim 1, wherein a second curvature of the second maximum curvature portion is larger than a first curvature of the first maximum curvature portion.

6. The optical terminator according to claim 1, wherein in the plan view of the main surface, the first termination waveguide is a spiral waveguide.

7. The optical terminator according to claim 1, wherein in the plan view of the main surface, the first termination waveguide is a first meandering waveguide.

8. The optical terminator according to claim 7, further comprising a second termination waveguide connected to the second end, wherein
the second termination waveguide faces the first meandering waveguide in a meandering direction of the first meandering waveguide.

9. The optical terminator according to claim 8, wherein in the plan view of the main surface, the second termination waveguide is a spiral waveguide.

10. The optical terminator according to claim 8, wherein in the plan view of the main surface, the second termination waveguide is a second meandering waveguide.

11. An optical wavelength filter comprising:
the optical terminator according to claim 1;
a ring resonator connected to the first end; and
a refractive index regulator to regulate a refractive index of the ring resonator.

12. An external cavity laser light source comprising:
the optical wavelength filter according to claim 11; and
an optical amplifier optically coupled to the ring resonator.
